(19) United States
(12) Patent Application Publication
(10) Pub. No.: US 2026/0068769 A1
(43) Pub. Date: Mar. 5, 2026

(54) HYBRID INTEGRATED OPTOELECTRONIC DEVICE

(71) Applicant: SHINKO ELECTRIC INDUSTRIES CO., LTD., Nagano (JP)

(72) Inventors: Yuji FURUTA, Nagano (JP); Tomoharu FUJII, Nagano (JP); Hisashi KANEDA, Nagano (JP); Futoshi TSUKADA, Nagano (JP)

(21) Appl. No.: 19/312,933

(22) Filed: Aug. 28, 2025

(30) Foreign Application Priority Data
Sep. 2, 2024 (JP) 2024-150989
May 15, 2025 (JP) 2025-081719

(51) Int. Cl. H01L 25/16; G02B 6/28; G02B 6/36; H01L 23/31

(52) U.S. Cl. CPC H01L 25/167; G02B 6/28; G02B 6/36

(57) ABSTRACT

A hybrid integrated optoelectronic device includes a first interconnect substrate, connecting members arranged on a first region of the first interconnect substrate, a second interconnect substrate facing the first region and electrically connected to the first interconnect substrate via the connecting members, a semiconductor device mounted on the first interconnect substrate or the second interconnect substrate, a photonic integrated circuit mounted on one side of the second interconnect substrate opposite a side with the first interconnect substrate and electrically connected to the semiconductor device, and an optical component arranged adjacent to the photonic integrated circuit via a first bonding material and configured to enable transmission and reception of optical signals with the photonic integrated circuit, wherein the optical component is fixed via a second bonding material to a second region of the first interconnect substrate which does not face the second interconnect substrate.

### CROSS-REFERENCE TO RELATED APPLICATIONS

The present application is based on and claims priority to Japanese Patent Applications No. 2024-150989 filed on Sep. 2, 2024 and No. 2025-081719 filed on May 15, 2025, with the Japanese Patent Office, the entire contents of which are incorporated herein by reference.

### FIELD

The disclosures herein relate to hybrid integrated optoelectronic devices.

### BACKGROUND

Optical connection structures for connecting optical waveguide devices to optical fibers or the like may be used in data centers or the like where various computers and data communication devices are installed. As an example of such optical connection structures, an optical connection component using a planar lightwave circuit is fixedly bonded to the end face of an input/output waveguide of an optical waveguide device, and that optical waveguide device and an optical fiber are optically connected via the planar lightwave circuit (See, for example, Patent Document 1).

In the optical connection structure as described above, the optical waveguide device and the optical connection component are fixedly bonded with a small adhesion area, which results in a weak adhesion strength. As a result, applying stress to the connection between the optical waveguide device and the optical connection component poses a risk of connection breakage, and the connection reliability cannot be said to be high.

Accordingly, there may be a need for a hybrid integrated optoelectronic device having an optical connection structure with high connection reliability.

### RELATED ART DOCUMENTS

### Patent Document

[Patent Document 1] Japanese Laid-Open Patent Publication No. 2020-64211

### SUMMARY

According to an aspect of the embodiment, a hybrid integrated optoelectronic device includes a first interconnect substrate, connecting members arranged on a first region of the first interconnect substrate, a second interconnect substrate facing the first region of the first interconnect substrate and electrically connected to the first interconnect substrate via the connecting members, a semiconductor device mounted on the first interconnect substrate or the second interconnect substrate, an encapsulating resin filling a space between the first region of the first interconnect substrate and the second interconnect substrate and covering the connecting members and the semiconductor device, a photonic integrated circuit mounted on one side of the second interconnect substrate opposite a side with the first interconnect substrate and electrically connected to the semiconductor device, and an optical component arranged adjacent to the photonic integrated circuit via a first bonding material and configured to enable transmission and reception of optical signals with the photonic integrated circuit, wherein the optical component is fixed via a second bonding material to a second region of the first interconnect substrate which does not face the second interconnect substrate.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of a hybrid integrated optoelectronic device according to a first embodiment;

FIG. 2 is a plan view illustrating an example of a first interconnect substrate of the hybrid integrated optoelectronic device according to the first embodiment;

FIG. 3 is a cross-sectional view illustrating an application example of the hybrid integrated optoelectronic device according to the first embodiment;

FIGS. 4A and 4B are drawings illustrating an example of a manufacturing process of the hybrid integrated optoelectronic device according to the first embodiment;

FIGS. 5A and 5B are drawings illustrating the example of the manufacturing process of the hybrid integrated optoelectronic device according to the first embodiment;

FIGS. 6A and 6B are drawings illustrating the example of the manufacturing process of the hybrid integrated optoelectronic device according to the first embodiment;

FIG. 7 is a cross-sectional view illustrating an example of a hybrid integrated optoelectronic device according to a first variation of the first embodiment;

FIG. 8 is a cross-sectional view illustrating an example of a hybrid integrated optoelectronic device according to the second variation of the first embodiment; and

FIG. 9 is a cross-sectional view illustrating a hybrid integrated optoelectronic device according to the third variation of the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### [Structure of Hybrid Integrated Optoelectronic Device]

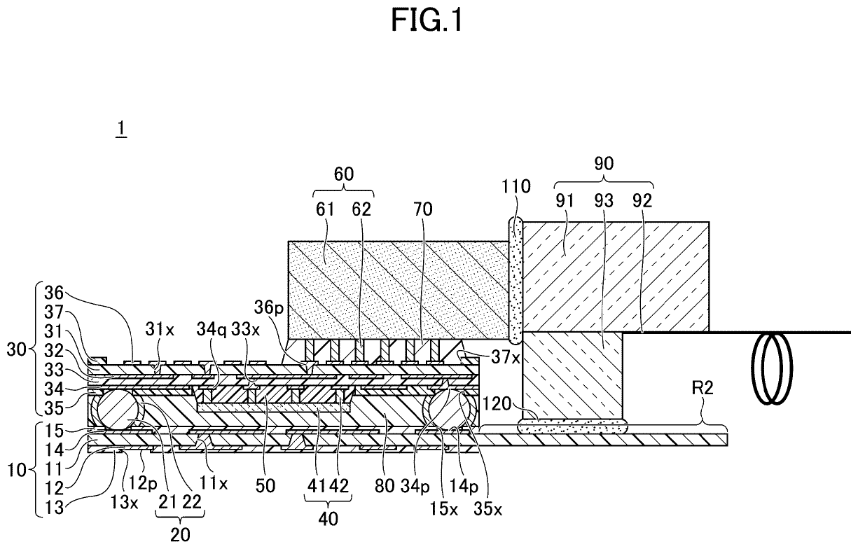

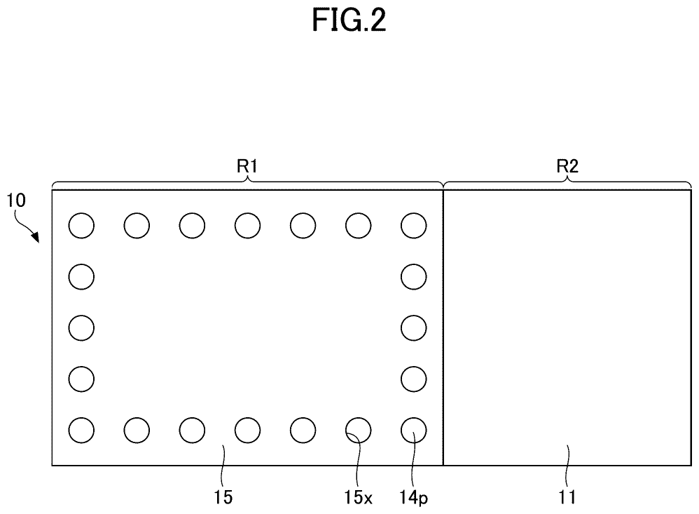

FIG. 1 is a cross-sectional view illustrating an example of a hybrid integrated optoelectronic device according to a first embodiment. FIG. 2 is a plan view illustrating an example of a first interconnect substrate that is a part of the hybrid integrated optoelectronic device according to the first embodiment. In FIG. 1, for convenience, the lead line and reference characters for the first region R1, as depicted in FIG. 2, are omitted.

Referring to FIGS. 1 and 2, a hybrid integrated optoelectronic device 1 includes a first interconnect substrate 10, connecting members 20, a second interconnect substrate 30, a semiconductor device 40, an underfill resin 50, a photonic integrated circuit 60, an underfill resin 70, an encapsulating resin 80, a fiber array 90, a first bonding material 110, and a second bonding material 120. The fiber array 90 is a typical example of an optical component according to the present invention.

In the hybrid integrated optoelectronic device 1, the first interconnect substrate 10 includes a first region R1 and a second region R2 continuous with the first region R1. The second interconnect substrate 30 faces the first region R1 of the first interconnect substrate 10 and is electrically connected to the first interconnect substrate 10 via the connecting members 20 arranged in the first region R1. Among surface regions of the first interconnect substrate 10, the region facing the second interconnect substrate 30 is the first region R1, and the region not facing the second interconnect substrate 30 is referred to as the second region R2.

The first interconnect substrate 10 is, for example, rectangular in plan view, and the first region R1 and the second region R2 may be arranged adjacent to each other along the longitudinal direction of the rectangle. However, the arrangement of the first region R1 and the second region R2 is not limited to the example illustrated in FIG. 2. For example, the second region R2 need not abut the entirety of one side of the first region R1, but may abut only a part of one side of the first region R1.

With respect to this embodiment, for convenience, the space extending away from the surface bearing a solder resist layer 37 of the hybrid integrated optoelectronic device 1 in FIG. 1 is referred to as an upper side or a first side, and the space extending away from the surface bearing a solder resist layer 13 is referred to as a lower side or a second side. The surface of a portion facing toward the upper side is referred to a first surface or an upper surface, and the surface of the portion facing toward the lower side is referred to a second surface or a lower surface. Nonetheless, the hybrid integrated optoelectronic device 1 may be positioned upside down when used, or may be arranged at any angle. The plan view of an object refers to the view of the object as seen from the direction normal to the first surface of the solder resist layer 37, and the plan shape of an object refers to the shape of the object as viewed from the direction normal to the first surface of the solder resist layer 37.

The first interconnect substrate 10 includes an insulating layer 11, an interconnect layer 12, the solder resist layer 13, an interconnect layer 14, and a solder resist layer 15.

In the first interconnect substrate 10, the insulating layer 11 may be, for example, a glass epoxy substrate made by impregnating a glass cloth with an insulating resin such as an epoxy-based resin. The insulating layer 11 may be, for example, a substrate made by impregnating a woven fabric or a nonwoven fabric such as glass fiber, carbon fiber, or aramid fiber with an insulating resin such as an epoxy-based resin. The thickness of the insulating layer 11 may be, for example, in the range of approximately 60 to 200 μm. In each of the drawings, the illustration of the glass cloth or the like is omitted.

The interconnect layer 12 is formed on the lower surface of the insulating layer 11. The interconnect layer 14 is formed on the upper surface of the insulating layer 11. Via holes 11x are formed in the insulating layer 11 to extend through the insulating layer 11 and reach the lower surface of the interconnect layer 14. The via holes 11x are each a truncated conical hole in which the diameter of the opening toward the solder resist layer 13 is larger than the diameter of the opening at the lower surface of the interconnect layer 14. The diameter of the opening of each of the via holes 11x toward the solder resist layer 13 may be, for example, about 50 μm.

The interconnect layer 12 includes via interconnects filling the via holes 11x and an interconnect pattern formed on the lower surface of the insulating layer 11. The lower surface of the interconnect layer 14 is in contact with the upper ends of the via interconnects filling the via holes 11x of the interconnect layer 12. That is, the interconnect layer 12 is electrically connected to the interconnect layer 14.

Copper (Cu) or the like may be used as the material of the interconnect layer 12. The thickness of the interconnect pattern of the interconnect layer 12 may be, for example, in the range of approximately 10 to 20 μm. The material of the interconnect layer 14 may be, for example, substantially the same as that of the interconnect layer 12. The thickness of the interconnect layer 14 may be, for example, substantially the same as that of the interconnect pattern of the interconnect layer 12.

The solder resist layer 13 is formed on the lower surface of the insulating layer 11 so as to cover the interconnect layer 12. The solder resist layer 13 may be made of, for example, photosensitive resin. The thickness of the solder resist layer 13 may be, for example, in the range of approximately 15 to 35 μm. The solder resist layer 13 has openings 13x, and parts of the interconnect layer 12 are exposed in the openings 13x. The interconnect layer 12 exposed in the openings 13x constitutes pads 12p. The pads 12p serve to provide electrical connection with a package substrate or the like.

The solder resist layer 13 may alternatively be formed to completely expose the pads 12p. In this case, the solder resist layer 13 may be configured such that the side surface of each pad 12p is in contact with the inner wall surface of a corresponding opening 13x, or the solder resist layer 13 may be configured such that there is a gap between the side surface of each pad 12p and the inner wall surface of a corresponding opening 13x.

If necessary, the lower surface of each pad 12p may have a metal layer formed thereon, or may be subjected to an antioxidant treatment such as an organic solderability preservative (OSP) treatment. Examples of the metal layer include an Au layer, a Ni/Au layer (a metal layer made by laminating a Ni layer and an Au layer in this order), and a Ni/Pd/Au layer (a metal layer made by laminating a Ni layer, a Pd layer, and an Au layer in this order). An external connection terminal such as a solder ball may be formed on the lower surface of a pad 12p.

The solder resist layer 15 is formed on the top surface of the insulating layer 11 so as to cover the interconnect layer 14. The material and thickness of the solder resist layer 15 may be substantially the same as those of the solder resist layer 13, for example. The solder resist layer 15 has openings 15x, and parts of the interconnect layer 14 are located within the openings 15x. The interconnect layer 14 exposed in the openings 15x constitutes pads 14p. The pads 14p serve to provide electrical connections with the connecting members 20. On the upper surface of each pad 14p, a metal layer of the same kind as previously described may be formed, or an oxidation prevention treatment such as an OSP treatment may be applied.

In the second region R2 of the example illustrated FIGS. 1 and 2, the lower surface of the insulating layer 11 is exposed beyond the solder resist layer 13, and the upper surface of the insulating layer 11 is exposed beyond the solder resist layer 15. Alternatively, the solder resist layers 13 and/or 15 may extend from the first region R1 to the second region R2 to cover part or all of the lower and/or upper surfaces of the insulating layer 11.

The second interconnect substrate 30 includes an insulating layer 31, an interconnect layer 32, an insulating layer 33, an interconnect layer 34, a solder resist layer 35, an interconnect layer 36, and a solder resist layer 37.

In the second interconnect substrate 30, the material and thickness of the insulating layer 31 may be substantially the same as that of the insulating layer 11, for example. The interconnect layer 32 is formed on the lower surface of the insulating layer 31. The material of the interconnect layer 32 may be substantially the same as that of the interconnect layer 12, for example. The thickness of the interconnect layer 32 may be substantially the same as that of the interconnect pattern of the interconnect layer 12, for example.

The insulating layer 33 is formed on the lower surface of the insulating layer 31 so as to cover the interconnect layer 32. An insulating resin such as a thermosetting epoxy-based resin may be used as the material of the insulating layer 33. The insulating layer 33 may contain a filler such as silica (SiO₂). The thickness of the insulating layer 33 may be, for example, in the range of approximately 15 to 35 μm.

The interconnect layer 34 is formed on the lower surface of the insulating layer 33. The interconnect layer 34 includes via interconnects that fill via holes 33x penetrating the insulating layer 33 and reaching the lower surface of the interconnect layer 32, and includes an interconnect pattern formed on the lower surface of the insulating layer 33.

The via holes 33x are each a truncated conical hole that has an opening toward the solder resist layer 35 and an end surface formed by the lower surface of the interconnect layer 32, with the area of the opening being larger than the area of the end surface. The material of the interconnect layer 34 may be substantially the same as that of the interconnect layer 12, for example. The thickness of the interconnect layer 34 may be substantially the same as that of the interconnect pattern of the interconnect layer 12, for example.

The solder resist layer 35 is a protective insulating layer formed on the lower surface of the insulating layer 33 so as to cover the interconnect layer 34. The material and thickness of the solder resist layer 35 may be substantially the same as those of the solder resist layer 13, for example. The solder resist layer 35 has openings 35x, and parts of the interconnect layer 34 are located within the openings 35x. The interconnect layer 34 located within the openings 35x constitutes pads 34p and 34q.

Each pad 34p is arranged so as to face a corresponding pad 14p of the first interconnect substrate 10. The pads 34p function as connection points for the connecting member 20. The pads 34q function as connection points for the semiconductor device 40. A plurality of pads 34q are formed on the side of the second interconnect substrate 30 toward the first interconnect substrate 10. The opening diameters may be set differently between the pads 34p electrically connected to the connecting members 20 and the pads 34q electrically connected to the semiconductor device 40. According to need, the undersurfaces of the pads 34p and 34q may be formed with a metal layer of the same kind as previously described or subjected to an oxidation prevention treatment such as an OSP treatment.

The interconnect layer 36 is formed on the upper surface of the insulating layer 31. The interconnect layer 36 includes via interconnects filling via holes 31x that penetrates the insulating layer 31 and reach the upper surface of the interconnect layer 32, and includes an interconnect pattern formed on the upper surface of the insulating layer 31.

The via holes 31x are each a truncated conical hole that has an opening toward the solder resist layer 37 and a bottom surface formed by the upper surface of the interconnect layer 32, with the area of the opening being larger than the area of the bottom surface. The lower ends of the via interconnects of the interconnect layer 36 filling the via holes 31x are in contact with the upper surface of the interconnect layer 32. That is, the interconnect layer 36 is electrically connected to the interconnect layer 32. The material of the interconnect layer 36 and the thickness of the interconnect pattern of the interconnect layer 36 may be substantially the same as those of the interconnect layer 12, for example.

The solder resist layer 37 is formed on the upper surface of the insulating layer 31. The material and thickness of the solder resist layer 37 may be substantially the same as those of the solder resist layer 13, for example. The solder resist layer 37 has an opening 37x, and the interconnect layer 36 are exposed in the opening 37x. The interconnect layer 36 exposed in the opening 37x constitutes pads 36p. The pads 36p function as connection points for the photonic integrated circuit 60. Some of the pads 36p may be used as external connection pads. On the upper surfaces of the pads 36p, a metal layer of the same kind as previously described may be formed, or an oxidation prevention treatment such as an OSP treatment may be applied.

The semiconductor device 40 is mounted on the side of the first interconnect substrate 10 toward the second interconnect substrate 30 or on the side of the second interconnect substrate 30 toward the first interconnect substrate 10. In the example illustrated in FIG. 1, the semiconductor device 40 is mounted on the side of the second interconnect substrate 30 toward the first interconnect substrate 10, and is electrically connected to the photonic integrated circuit 60 via the second interconnect substrate 30. Specifically, the semiconductor device 40 is flip-chip mounted on the lower surface of the second interconnect substrate 30 in a face-down state. The semiconductor device 40 includes a core 41 having a semiconductor integrated circuit, and electrodes 42 as connection terminals. The electrodes 42 of the semiconductor device 40 are electrically connected to the pads 34q of the second interconnect substrate 30 via solder or the like. The electrodes 42 may be, for example, gold bumps, solder bumps, copper posts with solder at the tips, or the like.

The semiconductor device 40 is, for example, a semiconductor chip. The semiconductor device 40 may alternatively be a semiconductor package in which insulating layers and redistribution interconnects are formed on the semiconductor chip. In addition to the semiconductor device 40, passive elements such as capacitors, inductors, and resistors may be mounted on either the first interconnect substrate 10 or the second interconnect substrate 30, or both.

The underfill resin 50 fills a space between the semiconductor device 40 and the lower surface of the second interconnect substrate 30. The material of the underfill resin 50 preferably has good fluidity. The material of the underfill resin 50 may be an insulating resin such as an epoxy-based resin.

The photonic integrated circuit 60 is mounted on the side of the second interconnect substrate 30 opposite the first interconnect substrate 10, and is electrically connected to the semiconductor device 40. Specifically, the photonic integrated circuit 60 is flip-chip mounted on the upper surface of the second interconnect substrate 30 in a face-down state. The photonic integrated circuit 60 includes a core 61 with optical waveguides or the like and electrodes 62 as connection terminals. The electrodes 62 of the photonic integrated circuit 60 are electrically connected to the pads 36p of the second interconnect substrate 30 via solder or the like. The electrodes 62 may be, for example, gold bumps, solder bumps, or copper posts with solder at the tips.

The photonic integrated circuit 60 (PIC) includes, for example, optical waveguides, light emitting elements, light receiving elements, and the like provided on a substrate made of silicon or the like. The photonic integrated circuit 60 is sometimes referred to as silicon photonics or the like. The photonic integrated circuit 60 may have the function of converting an optical signal input from the fiber array 90 into an electrical signal for output to the semiconductor device 40, and/or the function of converting an electrical signal input from the semiconductor device 40 into an optical signal for output to the fiber array 90.

At least a part of the photonic integrated circuit 60 preferably overlaps the semiconductor device 40 in plan view. Such an arrangement allows the photonic integrated circuit 60 and the semiconductor device 40 to be connected by a short interconnect path, thereby enabling high-speed and large-scale data transmission and reception between the photonic integrated circuit 60 and the semiconductor device 40.

The semiconductor device 40 may have the function of amplifying electrical signals input from the photonic integrated circuit 60. Electrical signals input from the photonic integrated circuit 60 are high-speed signals and thus easily attenuated. Connecting the photonic integrated circuit 60 and the semiconductor device 40 via short interconnects and amplifying the attenuating electrical signals in the semiconductor device 40 effectively improve the quality of the electrical signals output from the semiconductor device 40.

The underfill resin 70 fills a space between the photonic integrated circuit 60 and the upper surface of the second interconnect substrate 30. The material of the underfill resin 70 may be, for example, substantially the same material as the underfill resin 50.

The connecting members 20 are arranged between the pads 14p of the first interconnect substrate 10 and the pads 34p of the second interconnect substrate 30. The connecting members 20 have the function of electrically connecting the first interconnect substrate 10 and the second interconnect substrate 30 and to secure a predetermined distance between the first interconnect substrate 10 and the second interconnect substrate 30.

In this embodiment, as an example, a solder ball with a core is used as each connecting member 20. Each connecting member 20 includes a substantially spherical core 21 and a conductive material 22 covering the outer peripheral surface of the core 21, and the core 21 is arranged so as to be in contact with the pads 14p and 34p. The diameter of the core 21 before joining the first interconnect substrate 10 and the second interconnect substrate 30 may be, for example, in the range of approximately 100 μm to 300 μm, and may preferably be about 200 μm. The diameter of the entire connecting member 20 including the conductive material 22 before joining the first interconnect substrate 10 and the second interconnect substrate 30 may be, for example, in the range of approximately 150 μm to 350 μm, and may preferably be about 250 μm.

The core 21 may be, for example, a metal core made of a metal such as copper or a resin core made of resin. The conductive material 22 may be, for example, a solder material such as an alloy containing Pb, an alloy of Sn and Cu, an alloy of Sn and Sb, an alloy of Sn and Ag, and an alloy of Sn, Ag and Cu. The diameter of the core 21 may be determined in consideration of the height (thickness) of the semiconductor device 40.

The connecting member 20 is not limited to a solder ball with a core such as the core 21 and the conductive material 22 covering the outer peripheral surface of the core 21, but may be, for example, a solder ball without a core. When a solder ball without a core is used, the distance between the first interconnect substrate 10 and the second interconnect substrate 30 may be controlled by using an appropriate jig at the time of manufacturing the hybrid integrated optoelectronic device 1. Alternatively, a metal post such as a copper post or a metal bump such as a gold bump may be used as the connecting member 20.

Although the connecting members 20 are illustrated in a simple arrangement in FIG. 1, in actuality, a plurality of rows of connecting members 20 are arranged, for example, in a peripheral pattern. When the first interconnect substrate 10 and the second interconnect substrate 30 are rectangular in plan view, the connecting members 20 are disposed in a peripheral pattern, for example, along the periphery of the substrates. When the diameters of the connecting members 20 are about 150 μm, for example, the pitch of the connecting members 20 may be about 200μ m.

The encapsulating resin 80 fills a space between the first interconnect substrate 10 and the second interconnect substrate 30 to cover the connecting members 20 and the semiconductor device 40. For example, a mold resin may be used as the material of the encapsulating resin 80. The mold resin is an insulating resin mainly composed of a non-photosensitive thermosetting resin usable for transfer molding, compression molding, injection molding, etc. The mold resin may be, for example, an insulating resin such as a non-photosensitive thermosetting epoxy-based resin, and may contain a filler.

The fiber array 90 includes, for example, a base 91, a plurality of optical fibers 92, and a lid 93. The base 91 and the lid 93 may be formed of, for example, glass or resin. The fiber array 90 is disposed adjacent to the photonic integrated circuit 60 via the first bonding material 110, and may exchange optical signals with the photonic integrated circuit 60.

The gap between the fiber array 90 and the photonic integrated circuit 60 is, for example, about several tens of micrometers. The end of each optical waveguide of the photonic integrated circuit 60 faces the end of a corresponding optical fiber 92 via the first bonding material 110. With this arrangement, each optical waveguide of the photonic integrated circuit 60 may exchange an optical signal with the corresponding optical fiber 92. The first bonding material 110 is, for example, an optical adhesive having a good transmittance with respect to the wavelengths of optical signals exchanged between the fiber array 90 and the photonic integrated circuit 60.

The fiber array 90 is fixedly attached to the second region R2 of the first interconnect substrate 10, which does not face the second interconnect substrate 30, via the second bonding material 120. The second bonding material 120 may be arranged over the entire region where the lid 93 of the fiber array 90 and the second region R2 of the first interconnect substrate 10 face each other, or in a part thereof. For example, the second bonding material 120 may be arranged in the four corners of the region where the lid 93 of the fiber array 90 and the second region R2 of the first interconnect substrate 10 face each other. The second bonding material 120 may be an ultraviolet curing type or thermosetting type epoxy-based resin.

As described above, the hybrid integrated optoelectronic device 1 is such that the fiber array 90 is fixedly attached to the photonic integrated circuit 60 via the first bonding material 110, and is also fixedly attached to the second region R2 of the first interconnect substrate 10 via the second bonding material 120. This arrangement reduces the likelihood of concentration of stress at the connection point between the fiber array 90 and the photonic integrated circuit 60, thereby effectively reducing the risk of breakage at the connection point between the fiber array 90 and the photonic integrated circuit 60. That is, an optical connection structure with high connection reliability is effectively formed between the fiber array 90 and the photonic integrated circuit 60.

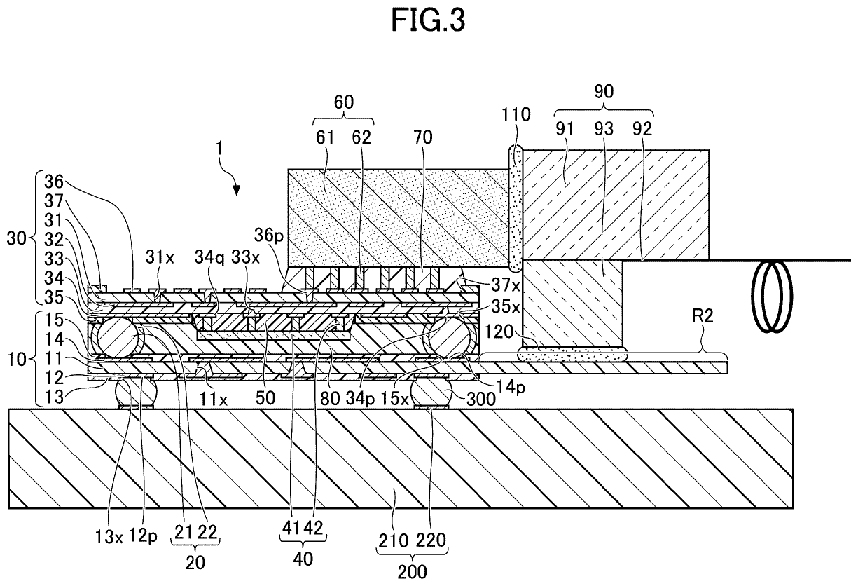

FIG. 3 is a cross-sectional view illustrating an application example of the hybrid integrated optoelectronic device according to the first embodiment. Referring to FIG. 3, the hybrid integrated optoelectronic device 1 is mounted on a package substrate 200. Specifically, the package substrate 200 includes a body 210 and pads 220 disposed on the upper surface of the body 210. The pads 220 are electrically connected to the pads 12p of the hybrid integrated optoelectronic device 1 via joints 300 which are solder balls or the like.

The package substrate 200 may include, for example, an embedded processor. The processor may be electrically connected to the semiconductor device 40 of the hybrid integrated optoelectronic device 1 via the package substrate 200.

The lower side of the package substrate 200 is connected to a mounting substrate such as a motherboard, for example. That is, the package substrate 200 is, for example, an interposer that relays the electrical connection between the hybrid integrated optoelectronic device 1 and another mounting substrate. The body 210 of the package substrate 200 is, for example, a resin substrate or a silicon substrate with multilayer interconnects. Use of the package substrate 200 effectively enlarges a pad pitch even when the pads of the hybrid integrated optoelectronic device 1 have a narrow pitch. This arrangement thus facilitates easy electrical connection between the hybrid integrated optoelectronic device 1 and another mounting substrate.

The optical connection structure with high connection reliability between the fiber array 90 and the photonic integrated circuit 60 is completed within the hybrid integrated optoelectronic device 1 while the device is in a stand-alone state, and does not depend on the package substrate 200. This arrangement allows easy handling of the hybrid integrated optoelectronic device 1, and effectively improves the degree of design freedom of the mounting structure using the hybrid integrated optoelectronic device 1.

### [Method of Making Hybrid Integrated Optoelectronic Device]

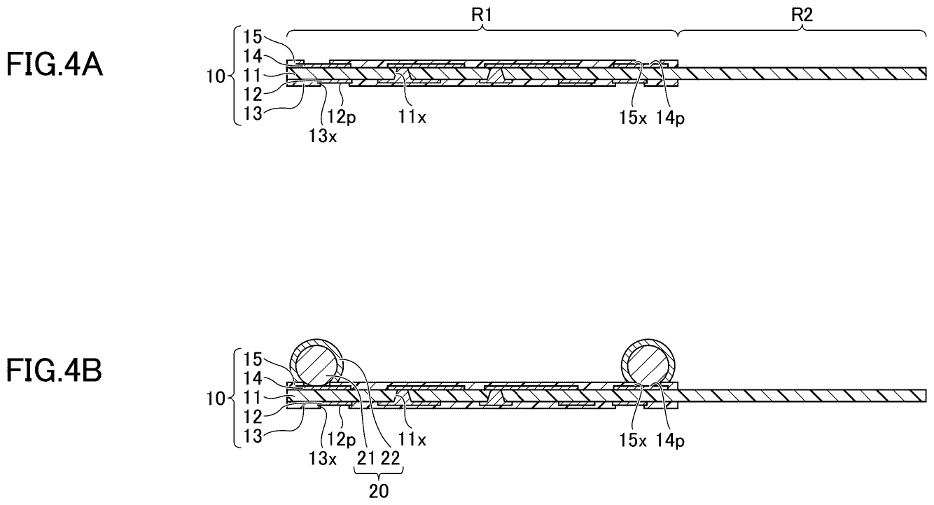

A method of making the hybrid integrated optoelectronic device according to the first embodiment is described below. FIGS. 4A and 4B through FIGS. 6A and 6B are drawings illustrating an example of the manufacturing process of the hybrid integrated optoelectronic device according to the first embodiment.

In the step illustrated in FIG. 4A, a first interconnect substrate 10 is fabricated. The first interconnect substrate 10 has, as regions defined thereon, a first region R1 that is to become the region facing the second interconnect substrate 30, and a second region R2 that is to become the region not facing the second interconnect substrate 30.

The first interconnect substrate 10 may be formed by, for example, a build-up method widely known in the art. Specifically, an insulating layer 11 formed of a glass epoxy substrate or the like is prepared. An interconnect layer 14 is then formed on the upper surface of the insulating layer 11. Next, via holes 11x exposing the lower surface of the interconnect layer 14 are formed through the insulating layer 11, followed by forming an interconnect layer 12 on the lower surface of the insulating layer 11. The interconnect layer 12 and the interconnect layer 14 are electrically connected through the insulating layer 11.

After the via holes 11x are formed, desmear treatment is preferably performed to remove resin residues adhering to the surface of the interconnect layer 14 exposed at the bottom of the via holes 11x. The via holes 11x may be formed by laser processing using, for example, a CO₂ laser. The interconnect layers 12 and 14 may be formed by an interconnect forming method of any given type such as a semi-additive method or a subtractive method. For example, the interconnect layers 12 and 14 may be formed by copper plating or the like.

A solder resist layer 13 covering the interconnect layer 12 is formed on the lower surface of the insulating layer 11, and a solder resist layer 15 covering the interconnect layer 14 is formed on the upper surface of the insulating layer 11. The solder resist layer 13 may be formed by applying, for example, an insulating resin such as a photosensitive epoxy-based resin liquid or paste to the lower surface of the insulating layer 11 by a screen-printing method, a roll coating method, or a spin coating method so as to cover the interconnect layer 12.

Similarly, the solder resist layer 15 may be formed by applying, for example, an insulating resin such as a photosensitive epoxy-based resin liquid or paste to the upper surface of the insulating layer 11 by a similar method so as to cover the interconnect layer 14. Alternatively, instead of applying resin liquid or paste, an insulating resin such as a photosensitive epoxy-based resin film may be laminated.

By exposing and developing the coated or laminated insulating resin, openings 13x and 15x are formed in the solder resist layers 13 and 15, respectively, thereby forming pads 12p and 14p (photolithography). Through this process, the manufacture of the first interconnect substrate 10 is completed. The openings 13x and 15x may be formed by laser processing or blast processing. The plan shapes of the openings 13x and 15x may be, for example, circular. The diameters of the openings 13x and 15x may be selected as appropriate according to the object to be connected.

In the step illustrated in FIG. 4B, connecting members 20 are placed on the pads 14p exposed in the openings 15x of the solder resist layer 15 of the first interconnect substrate 10. The conductive materials 22 of the connecting members 20 are then heated to a predetermined temperature to be melted, followed by being cured and bonded to the pads 14p. A part of the core 21 of each connecting member 20 is in contact with a corresponding pad 14p. The connecting members 20 are arranged in a peripheral pattern, for example.

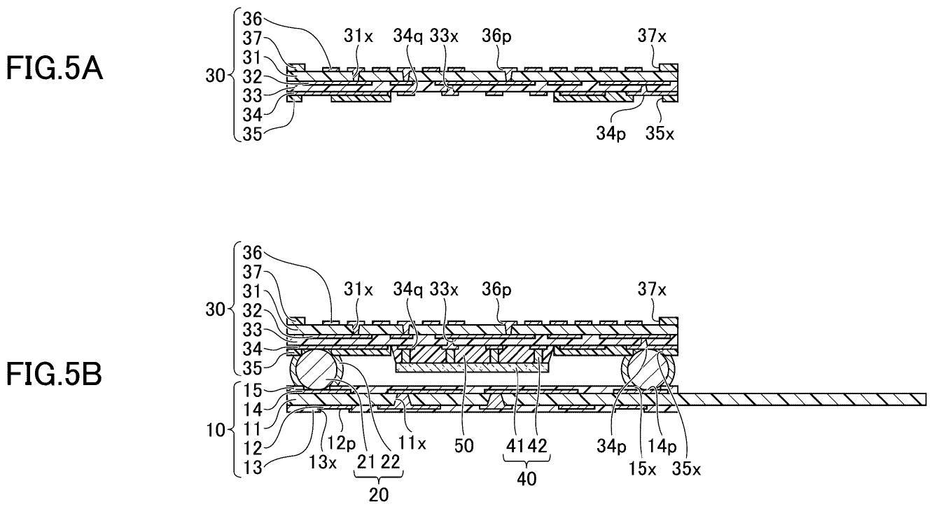

In the step illustrated in FIG. 5A, a second interconnect substrate 30 is fabricated. The second interconnect substrate 30 may be fabricated by, for example, a build-up method widely known in the art. Specifically, an insulating layer 31 formed of a glass epoxy substrate or the like is prepared, and an interconnect layer 32 is formed on the lower surface of the insulating layer 31. Via holes 31x exposing the upper surface of the interconnect layer 32 are formed through the insulating layer 31, followed by forming an interconnect layer 36 on the upper surface of the insulating layer 31. The interconnect layer 32 and the interconnect layer 36 are electrically connected through the insulating layer 31.

After the via holes 31x are formed, desmearing is preferably performed to remove resin residues adhered to the surface of the interconnect layer 32 exposed at the bottom of the via holes 31x. The via holes 31x may be formed by a laser processing method using, for example, a CO₂ laser. The interconnect layers 32 and 36 may be formed by an interconnect forming method of any type such as a semi-additive method or a subtractive method.

An insulating resin film such as a thermosetting epoxy-based resin film is laminated on the lower surface of the insulating layer 31 so as to cover the interconnect layer 32, thereby forming the insulating layer 33. Alternatively, instead of laminating the insulating resin film such as a thermosetting epoxy-based resin film, an insulating resin such as a thermosetting epoxy-based resin liquid or paste may be applied and cured to form the insulating layer 33.

Via holes 33x are formed in the insulating layer 33 to extend through the insulating layer 33 and expose the lower surface of the interconnect layer 32. The via holes 33x may be formed by a laser processing method using, for example, a CO₂ laser. After the via holes 33x are formed, desmearing is preferably performed to remove resin residues adhering to the surface of the interconnect layer 32 exposed at the bottom of the via holes 33x.

An interconnect layer 34 is formed on the lower surface side of the insulating layer 33. The interconnect layer 34 includes via interconnects filling the via holes 33x and an interconnect pattern formed on the lower surface of the insulating layer 33. The interconnect layer 34 is electrically connected to the interconnect layer 32 exposed at the bottom of the via holes 33x. The interconnect layer 34 may be formed by an interconnect formation method of any kind such as a semi-additive method or a subtractive method.

Similarly to the solder resist layer 13 and the like of the first interconnect substrate 10, a solder resist layer 35 covering the interconnect layer 34 is formed on the lower surface of the insulating layer 33, and a solder resist layer 37 covering the interconnect layer 36 is formed on the upper surface of the insulating layer 31. Similarly to the openings 13x and the like of the first interconnect substrate 10, openings 35x and 37x are formed in the solder resist layers 35 and 37, respectively, thereby forming pads 34p and 36p (photolithography method). Through this process, the manufacture of the second interconnect substrate 30 is completed. The second interconnect substrate 30 has a rectangular shape having a smaller area than the first interconnect substrate 10 in plan view, for example.

In the step illustrated in FIG. 5B, a semiconductor device 40 having a core 41 and electrodes 42 is prepared, and the semiconductor device 40 is mounted on the second interconnect substrate 30 such that the electrodes 42 are joined to the pads 34q. Specifically, for example, a solder material paste is applied on the pads 34q. Then, the electrodes 42 of the semiconductor device 40 are aligned with the pads 34q, followed by placing the semiconductor device 40 on the second interconnect substrate 30. The solder material is heated and melted by reflow or the like, and then solidified. With this arrangement, the electrodes 42 of the semiconductor device 40 are electrically connected to the pads 34q of the second interconnect substrate 30 via the solder material.

The second interconnect substrate 30 is stacked on the first interconnect substrate 10 with the semiconductor device 40 interposed therebetween such that the connecting members 20 are at positions aligned with the pads 34p. The conductive materials 22 of the connecting members 20 are heated and melted by a heater or the like, and then solidified. As a result, the lower sides of the cores 21 of the connecting members 20 are joined to the pads 14p of the first interconnect substrate 10, and the upper sides thereof are joined to the pads 34p of the second interconnect substrate 30. That is, the first interconnect substrate 10 and the second interconnect substrate 30 are electrically connected via the connecting members 20. In addition, the cores 21 of the connecting members 20 secure a predetermined distance between the first interconnect substrate 10 and the second interconnect substrate 30.

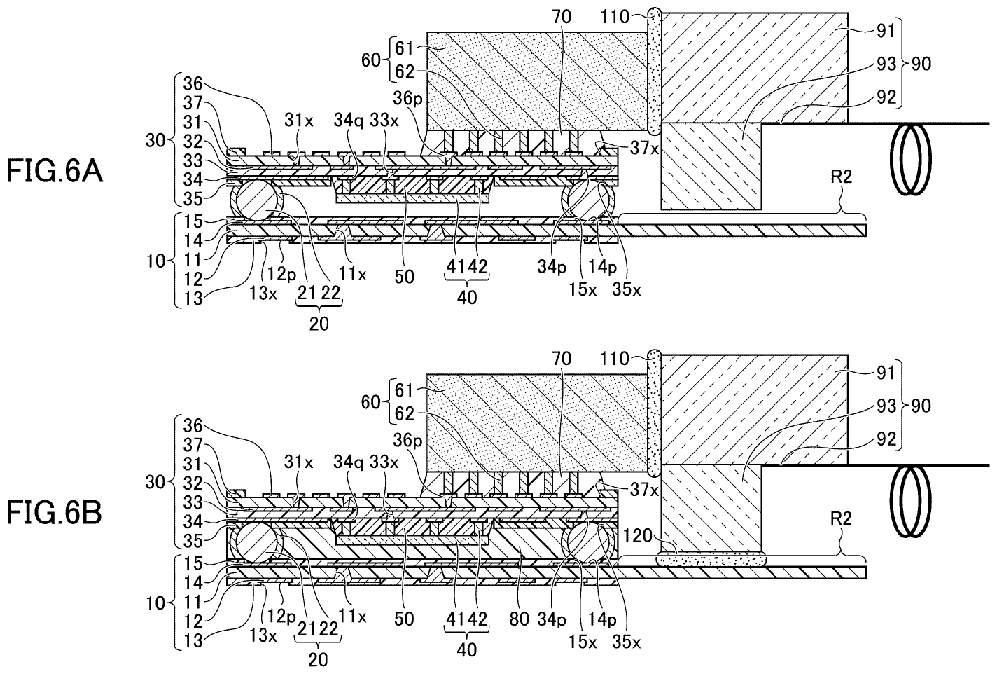

In the step illustrated in FIG. 6A, a photonic integrated circuit 60 having a core 61 and electrodes 62 is prepared, and the photonic integrated circuit 60 is mounted on the side of the second interconnect substrate 30 opposite the first interconnect substrate 10 such that the electrodes 62 are joined to the pads 36p. Specifically, for example, a solder material paste is applied on the pads 36p. The electrodes 62 of the photonic integrated circuit 60 and the pads 36p are aligned with each other, followed by placing the photonic integrated circuit 60 on the side of the second interconnect substrate 30 opposite the first interconnect substrate 10. Thereafter, the solder material is heated and melted by reflow or the like, and then solidified. With this arrangement, the electrodes 62 of the photonic integrated circuit 60 are electrically connected to the pads 36p of the second interconnect substrate 30 via the solder material.

Subsequently, a fiber array 90 having a base 91, a plurality of optical fibers 92, and a lid 93 is prepared. The fiber array 90 is arranged on the second region R2 of the first interconnect substrate 10 with the lid 93 facing downward, and the base 91 of the fiber array 90 is joined to the photonic integrated circuit 60 via a first bonding material 110 such that each optical fiber 92 is optically coupled to a corresponding optical waveguide of the photonic integrated circuit 60. For example, the base 91 of the fiber array 90 and the photonic integrated circuit 60 are temporarily fixed by an uncured first bonding material 110. Then, active alignment is performed to position each optical fiber 92 to be optically connected to a corresponding optical waveguide of the photonic integrated circuit 60, and, in that state, the uncured first bonding material 110 is cured.

In the step illustrated in FIG. 6B, the lid 93 of the fiber array 90 is fixed to the second region R2 of the first interconnect substrate 10 via a second bonding material 120. For example, uncured ultraviolet-curable or thermosetting epoxy resin or the like is injected into a space between the lid 93 and the second region R2 of the first interconnect substrate 10, and then cured.

Since the fiber array 90 fixed to the photonic integrated circuit 60 via the first bonding material 110 is also fixed to the second region R2 of the first interconnect substrate 10 by the second bonding material 120, stress is less likely to be concentrated at the connection between the fiber array 90 and the photonic integrated circuit 60. This arrangement effectively reduces the likelihood of breakage of the connection between the fiber array 90 and the photonic integrated circuit 60. That is, an optical connection structure with high connection reliability is effectively formed between the fiber array 90 and the photonic integrated circuit 60.

An encapsulating resin 80 is provided to fill the space between the first region R1 of the first interconnect substrate 10 and the second interconnect substrate 30, thereby covering the connecting member 20 and the semiconductor device 40. The encapsulating resin 80 may be, for example, an insulating resin such as a thermosetting epoxy-based resin containing a filler. The encapsulating resin 80 may be formed by, for example, a transfer molding method using an encapsulation mold.

The step of fixing the lid 93 of the fiber array 90 to the second region R2 of the first interconnect substrate 10 via the second bonding material 120 and the step of forming the encapsulating resin 80 between the first region R1 of the first interconnect substrate 10 and the second interconnect substrate 30 may be reversed in order.

By following these steps, the fabrication of the hybrid integrated optoelectronic device 1 is completed. According to need, external connection terminals such as solder balls may be formed on the pads 12p of the first interconnect substrate 10.

### <First Variation of First Embodiment>

A first variation of the first embodiment differs from the first embodiment in which the second bonding member is separate from the encapsulating resin, and is directed to an example in which the second bonding member is a part of the encapsulating resin, i.e., the encapsulating resin is also used as the second bonding member.

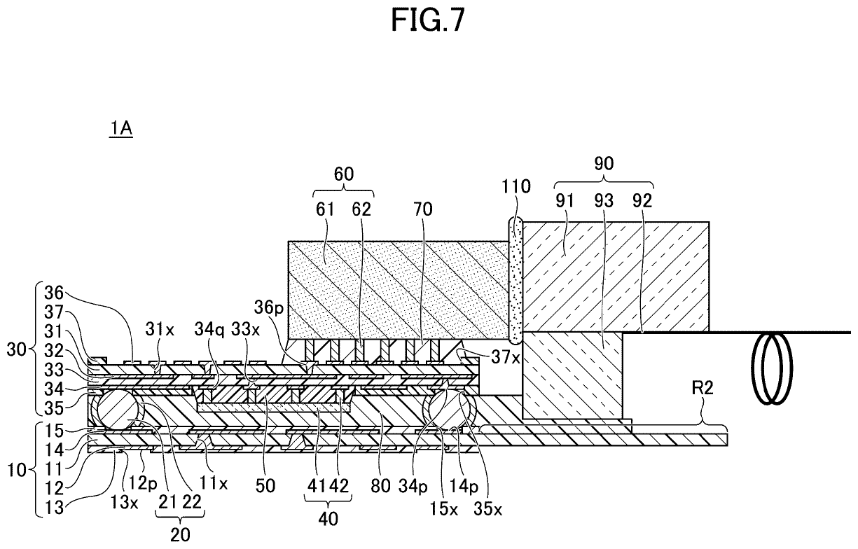

FIG. 7 is a cross-sectional view illustrating an example of a hybrid integrated optoelectronic device according to the first variation of the first embodiment. Referring to FIG. 7, a hybrid integrated optoelectronic device 1A, the encapsulating resin 80 extends from the first region R1 to the second region R2 of the first interconnect substrate 10 to enter the space between the second region R2 and the lid 93 of the fiber array 90, and functions as a second bonding member for fixing the fiber array 90 to the first interconnect substrate 10.

In the step of FIG. 6B, the encapsulating resin 80 may be provided to fill the space between the first region R1 of the first interconnect substrate 10 and the second interconnect substrate 30, and may further extend from the first region R1 to the second region R2 of the first interconnect substrate 10 to enter the space between the second region R2 and the lid 93 of the fiber array 90. The encapsulating resin 80 may be formed, for example, by a transfer molding method using an encapsulation mold.

In the hybrid integrated optoelectronic device 1A, since the fiber array 90 fixed to the photonic integrated circuit 60 via the first bonding material 110 is also fixed to the second region R2 of the first interconnect substrate 10 by the encapsulating resin 80, stress is less likely concentrated at the connection between the fiber array 90 and the photonic integrated circuit 60. This arrangement effectively reduces the likelihood of breakage of the connection between the fiber array 90 and the photonic integrated circuit 60. That is, an optical connection structure with high connection reliability is effectively formed between the fiber array 90 and the photonic integrated circuit 60.

### <Second Variation of First Embodiment>

The second variation of the first embodiment is directed to an example in which the fiber array is bonded to the encapsulating resin via the second bonding material.

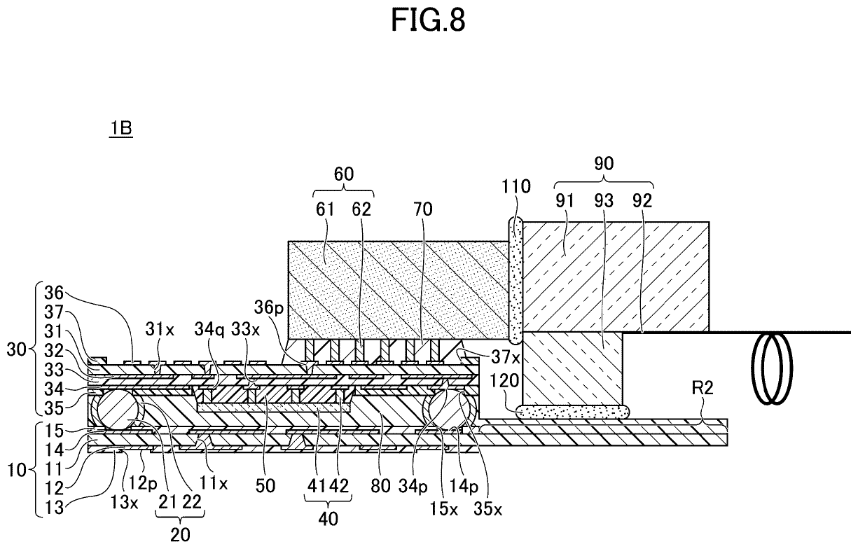

FIG. 8 is a cross-sectional view illustrating an example of a hybrid integrated optoelectronic device according to the second variation of the first embodiment. Referring to FIG. 8, a hybrid integrated optoelectronic device 1B is such that the encapsulating resin 80 extends from the first region R1 to the second region R2 of the first interconnect substrate 10. The encapsulating resin 80 may be provided, for example, over the entire second region R2. The encapsulating resin 80 may be provided, for example, over the entire upper surface of the insulating layer 11 located in the second region R2.

The fiber array 90 is fixed to the encapsulating resin 80 located in the second region R2 of the first interconnect substrate 10 via the second bonding material 120. The second bonding material 120 may be disposed over the entire area where the fiber array 90 and the encapsulating resin 80 face each other or in a part of the area. For example, the second bonding material 120 may be disposed in the four corners of the area where the fiber array 90 and the encapsulating resin 80 face each other.

The thickness of the encapsulating resin 80 located in the second region R2 is preferably determined such that the thickness of the second bonding material 120 between the encapsulating resin 80 located in the second region R2 and the fiber array 90 is in the range of 10 μm to 50 μm. This thickness of the second bonding material 120 effectively reduces its shrinkage that would occur due to heat generated when the second bonding material 120 is heated and cured. As a result, tilting of the fiber array 90 due to the heat-induced shrinkage of the second bonding material 120 is less likely to occur, thereby effectively suppressing optical axis misalignment between the optical waveguides of the photonic integrated circuit 60 and the optical fibers 92 of the fiber array 90.

To manufacture the hybrid integrated optoelectronic device 1B, for example, after the process illustrated in FIG. 5B, the encapsulating resin 80 is formed to fill the space between the first region R1 of the first interconnect substrate 10 and the second interconnect substrate 30, and to extend from the first region R1 to the second region R2 of the first interconnect substrate 10. The encapsulating resin 80 may be formed by, for example, a transfer molding method using an encapsulation mold. With this arrangement, the encapsulating resin 80 is formed before arranging the photonic integrated circuit 60 and the fiber array 90, so that the photonic integrated circuit 60 and the fiber array 90 need not be put into the encapsulation mold. This arrangement is thus preferable, inasmuch as the photonic integrated circuit 60 and the fiber array 90 are not damaged.

After the encapsulating resin 80 is cured, the photonic integrated circuit 60 is mounted on the side of the second interconnect substrate 30 opposite the first interconnect substrate 10. The fiber array 90 is then arranged on the second region R2 of the first interconnect substrate 10 with the lid 93 facing downward, and the base 91 of the fiber array 90 is joined to the photonic integrated circuit 60 via the first bonding material 110 such that each optical fiber 92 is optically coupled to a corresponding optical waveguide of the photonic integrated circuit 60.

Subsequently, an uncured ultraviolet-curing or thermosetting epoxy resin or the like is injected to the space between the lid 93 of the fiber array 90 and the encapsulating resin 80 located in the second region R2, and cured to form the second bonding material 120. Through this process, the manufacture of the hybrid integrated optoelectronic device 1B is completed. Alternatively, an uncured epoxy resin or the like may be applied to the encapsulating resin 80 located in the second region R2 before optically connecting the fiber array 90 to the photonic integrated circuit 60. In such an arrangement, the fiber array 90 is optically coupled to the photonic integrated circuit 60 first, and, then, the uncured epoxy resin or the like is cured to form the second bonding material 120.

In the hybrid integrated optoelectronic device 1B, the fiber array 90 is fixed to the photonic integrated circuit 60 by the first bonding material 110, and is also fixed to the encapsulating resin 80 located in the second region R2 of the first interconnect substrate 10 by the second bonding material 120. With this arrangement, stress is less likely to be concentrated in the connection between the fiber array 90 and the photonic integrated circuit 60, which effectively reduces the likelihood of breakage of the connection between the fiber array 90 and the photonic integrated circuit 60. That is, an optical connection structure with high connection reliability is effectively formed between the fiber array 90 and the photonic integrated circuit 60.

In the hybrid integrated optoelectronic device 1B, the provision of the encapsulating resin 80 extending from the first region R1 to the second region R2 of the first interconnect substrate 10 effectively improves the rigidity of the second region R2 of the first interconnect substrate 10. This effectively reduces the occurrence of warpage and deflection in the second region R2 of the first interconnect substrate 10. From the viewpoint of improving the rigidity of the second region R2, the thickness of the encapsulating resin 80 located in the second region R2 is preferably 50 μm or more. The thickness of the encapsulating resin 80 located in the second region R2 may be the same as that of the encapsulating resin 80 located in the first region R1. From the viewpoint of improving the rigidity of the second region R2, the encapsulating resin 80 is preferably provided over the entire second region R2.

### <Third Variation of First Embodiment>

The third variation of the first embodiment is directed to an example in which a connector 150 is arranged in place of the fiber array 90.

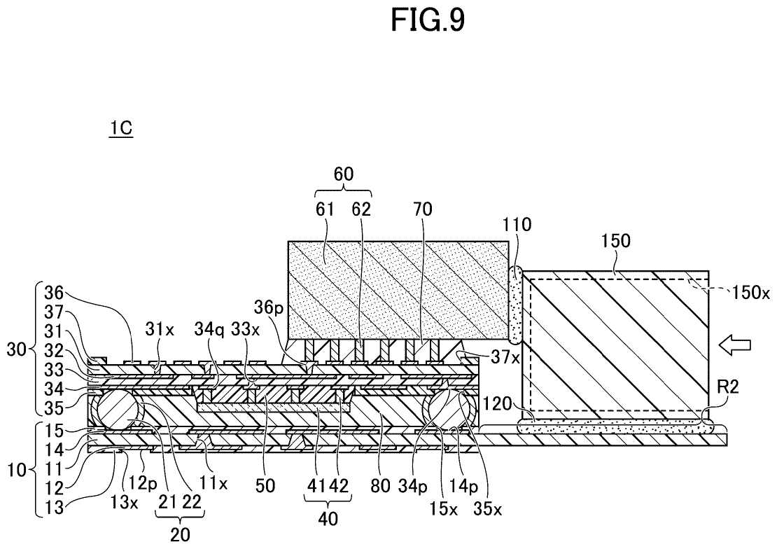

FIG. 9 is a cross-sectional view illustrating an example of a hybrid integrated optoelectronic device according to the third variation of the first embodiment. Referring to FIG. 9, a hybrid integrated optoelectronic device IC is such that the connector 150 is arranged adjacent to the photonic integrated circuit 60 via the first bonding material 110. The connector 150 is fixed to the second region R2 of the first interconnect substrate 10 by the second bonding material 120.

The connector 150 is a female connector and may be formed of, for example, transparent resin. Alternatively, the connector 150 may be formed of opaque resin, and may have an opening that allows transmission and reception of optical signals and that is formed in a region facing the optical waveguides of the photonic integrated circuit 60.

The connector 150 has an insertion hole 150x that opens on the side opposite the photonic integrated circuit 60, and is connectable with a fiber array having optical fibers. When the connector 150 and the fiber array are connected to each other, the photonic integrated circuit 60 is able to exchange optical signals with the optical fibers. For example, a male connector connected to the fiber array may be inserted into the insertion hole 150x from the direction indicated by the arrow, so that the optical fibers of the fiber array and the optical waveguides of the photonic integrated circuit 60 are aligned with each other to establish optical connections between them. Alternatively, the connector 150 may be a male type and the connector connected to the fiber array may be a female type.

As described above, the optical component according to the present invention is not limited to the fiber array 90, but may be the connector 150 or the like as long as it is arranged adjacent to the photonic integrated circuit 60 via the first bonding material 110 and contributes to the facilitation of transmission and reception of optical signals with the photonic integrated circuit 60.

When the optical component according to the present invention is the connector 150, stress may be repeatedly applied to the connection between the connector 150 and the photonic integrated circuit 60 when the fiber array or the like is attached to and detached from the connector 150. Accordingly, fixing the connector 150 to the second region R2 of the first interconnect substrate 10 via the second bonding material 120 offers significant technical advantages, inasmuch as the stress applied to the connection between the connector 150 and the photonic integrated circuit 60 is reduced. It is evident that the encapsulating resin 80 functioning as the second bonding material 120 may be used to fix the connector 150 to the first interconnect substrate 10. Alternatively, the encapsulating resin 80 may be extended from the first region R1 to the second region R2, and the connector 150 may be joined to the encapsulating resin 80 located in the second region R2 via the second bonding material 120.

According to at least one embodiment, a hybrid integrated optoelectronic device having an optical connection structure with high connection reliability is effectively provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A hybrid integrated optoelectronic device comprising:
a first interconnect substrate;
connecting members arranged on a first region of the first interconnect substrate;
a second interconnect substrate facing the first region of the first interconnect substrate and electrically connected to the first interconnect substrate via the connecting members;
a semiconductor device mounted on the first interconnect substrate or the second interconnect substrate;
an encapsulating resin filling a space between the first region of the first interconnect substrate and the second interconnect substrate and covering the connecting members and the semiconductor device;
a photonic integrated circuit mounted on one side of the second interconnect substrate opposite a side with the first interconnect substrate and electrically connected to the semiconductor device; and
an optical component arranged adjacent to the photonic integrated circuit via a first bonding material and configured to enable transmission and reception of optical signals with the photonic integrated circuit,
wherein the optical component is fixed via a second bonding material to a second region of the first interconnect substrate which does not face the second interconnect substrate.

2. The hybrid integrated optoelectronic device according to claim 1, wherein the encapsulating resin extends from the first region to the second region and enters a space between the second region and the optical component to function as the second bonding material.

3. The hybrid integrated optoelectronic device according to claim 1, wherein the second bonding material is separate from the encapsulating resin.

4. The hybrid integrated optoelectronic device according to claim 3, wherein the encapsulating resin extends from the first region to the second region, and the optical component is fixed to the encapsulating resin located in the second region via the second bonding material.

5. The hybrid integrated optoelectronic device according to claim 4, wherein the encapsulating resin is located over an entirety of the second region.

6. The hybrid integrated optoelectronic device according to claim 1, wherein the optical component includes an optical fiber, and the photonic integrated circuit is capable of exchanging optical signals with the optical fiber.

7. The hybrid integrated optoelectronic device according to claim 1, wherein the optical component is a connector configured to be connected to a fiber array including optical fibers, and
wherein, when the connector is connected to the fiber array, the photonic integrated circuit is able to exchange optical signals with the optical fibers.

8. The hybrid integrated optoelectronic device according to claim 1, wherein the photonic integrated circuit has at least one of:
a function of converting an optical signal input from the optical component into an electrical signal for output to the semiconductor device; or
a function of converting an electrical signal input from the semiconductor device into an optical signal for output to the optical component.

9. The hybrid integrated optoelectronic device according to claim 8, wherein the semiconductor device is mounted on the side of the second interconnect substrate with the first interconnect substrate, and is electrically connected to the photonic integrated circuit via the second interconnect substrate, and
wherein the photonic integrated circuit overlaps with the semiconductor device at least partially in plan view.

10. The hybrid integrated optoelectronic device according to claim 9, wherein the semiconductor device has a function of amplifying the electrical signal input from the photonic integrated circuit.
